(19) United States
(12) Patent Application Publication
(10) Pub. No.: US 2026/0066218 A1
(43) Pub. Date: Mar. 5, 2026

(54) PLASMA PROCESSING APPARATUS

(71) Applicant: Tokyo Electron Limited, Tokyo (JP)

(72) Inventors: Munehisa SEMOTO, Nirasaki City (JP); Mitsutoshi ASHIDA, Nirasaki City (JP); Kazushi KANEKO, Nirasaki City (JP)

(21) Appl. No.: 19/303,542

(22) Filed: Aug. 19, 2025

(30) Foreign Application Priority Data
Aug. 30, 2024 (JP) 2024-148353

(51) Int. Cl. H01J 37/244; H01J 37/32

(52) U.S. Cl. CPC H01J 37/244; H01J 37/32082; H01J 2237/24564

(57) ABSTRACT

A plasma processing apparatus includes: a processing chamber disposed within a processing container; a stage located within the processing chamber and on which a substrate is placed; an upper electrode facing the stage; a waveguide located along the upper electrode and through which radio-frequency power in a VHF or UHF band propagates; a dielectric ring separating the processing chamber from the waveguide; and four or more electric field sensors located in a circumferential direction of the dielectric ring, wherein the electric field sensors are disposed at positions where, when a reference position is 0, an angle formed by a straight line connecting a center of the dielectric ring and one of the electric field sensors and a straight line connecting the center of the dielectric ring and each of the electric field sensors is represented by 0, (t₁·π/2+π/6), (t₂·π/2+2π/6), and (t₃·π/2+3π/6), where t₁, t₂, and t₃ are integers including 0.

### CROSS-REFERENCE TO RELATED APPLICATION

This application is based upon and claims the benefit of priority from Japanese Patent Application No. 2024-148353, filed on Aug. 30, 2024, the entire contents of which are incorporated herein by reference.

### TECHNICAL FIELD

The present disclosure relates to a plasma processing apparatus.

### BACKGROUND

For example, Patent Document 1 aims to measure a state of a chamber that generates plasma, and discloses that “a traveling wave is applied to an electrode in a plasma chamber via a matcher from a radio-frequency power supply (its frequency is, for example, 2.4 GHZ)” and that “a signal measurer receives a voltage applied to the electrode in the plasma chamber and a current flowing through the electrode from a VI probe disposed between the matcher and the plasma chamber.”

### PRIOR ART DOCUMENTS

### Patent Documents

Patent Document 1: Japanese Patent Laid-Open Publication No. 2013-251071

### SUMMARY

According to one embodiment of the present disclosure, a plasma processing apparatus includes: a processing chamber disposed within a processing container; a stage located within the processing chamber and on which a substrate is placed; an upper electrode facing the stage; a waveguide located along the upper electrode and through which radio-frequency power in a VHF band or a UHF band propagates; a dielectric ring separating the processing chamber from the waveguide; and four or more electric field sensors located in a circumferential direction of the dielectric ring, wherein the four or more electric field sensors are disposed at positions where, when a reference position is 0, an angle formed by a straight line connecting a center of the dielectric ring and one of the four or more electric field sensors and a straight line connecting the center of the dielectric ring and each of the four or more electric field sensors is represented by 0, (t₁·π/2+π/6), (t₂·π/2+2π/6), and (t₃·π/2+3π/6), where t₁, t₂, and t₃ are integers including 0.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a plasma processing apparatus according to a first embodiment.

FIG. 2 is a cross-sectional view taken along line I-I in FIG. 1.

FIG. 3 is a diagram showing an example of a monitor Vpp value of a voltage sensor placed at an output of a matcher and a sensor value of an electric field sensor placed at a radio-frequency power introducer close to a plasma load.

FIG. 4 is a diagram showing an example of the Vpp value and the sensor value of the electric field sensor for each frequency when a variable frequency power supply is used as a VHF power supply.

FIG. 5 is a diagram showing an example of an electric field pattern for each TM mode directly below an upper electrode.

FIG. 6 is a diagram showing an example of circumferential disposition of the electric field sensor.

FIG. 7 is a diagram showing an example of the sensor value of the electric field sensor in each TM mode.

FIG. 8 is a diagram showing an example of the sensor value of the electric field sensor in each TM mode.

FIG. 9 is a diagram showing an example of the sensor value of the electric field sensor in each TM mode.

FIG. 10 is a diagram showing an example of the sensor value of the electric field sensor in each TM mode.

FIG. 11 is a diagram showing an example of the sensor value of the electric field sensor in each TM mode.

FIG. 12 is a diagram for explaining an example of circumferential disposition of the electric field sensor.

FIG. 13 is a schematic cross-sectional view showing an example of a plasma processing apparatus according to a second embodiment.

FIG. 14 is a cross-sectional view taken along line II-II in FIG. 13.

FIG. 15 is a schematic cross-sectional view showing an example of a plasma processing apparatus according to a third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the disclosed plasma processing apparatus are described below in detail with reference to the drawings. The plasma processing apparatus according to the present disclosure is not limited to these embodiments, and the following embodiments may be appropriately combined within a range that does not cause a contradiction in each configuration and each processing content of the present disclosure.

The figures referred to below are schematic for convenience of explanation. Therefore, details may be omitted, and dimensional ratios do not necessarily correspond to the actual ones.

### First Embodiment

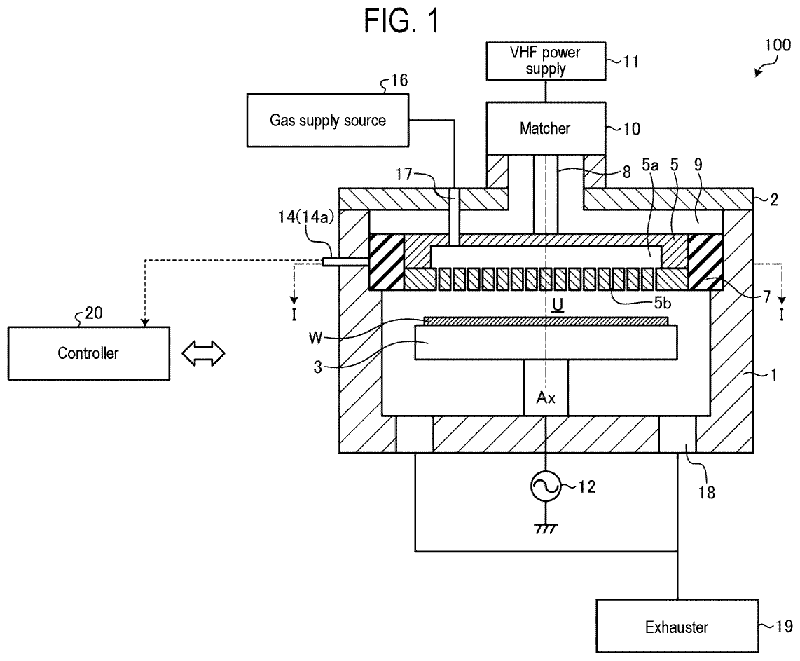

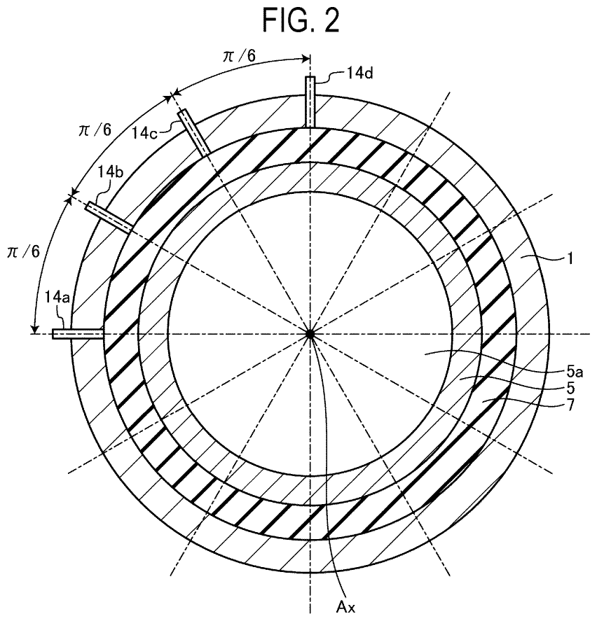

A plasma processing apparatus according to a first embodiment of the present disclosure is described with reference to FIGS. 1 and 2. FIG. 1 is a schematic cross-sectional view showing an example of the plasma processing apparatus according to the first embodiment. FIG. 2 is a cross-sectional view taken along line II in FIG. 1.

The plasma processing apparatus 100 includes a VHF (Very High Frequency) power supply 11, and is an example of an apparatus that generates plasma by using radio-frequency power in a VHF band of 30 MHz to 300 MHz output from the VHF power supply 11 and performs plasma processing on a substrate. However, the plasma processing apparatus 100 may include a UHF (Ultra High Frequency) power supply instead of the VHF power supply 11, generate plasma by using radio-frequency power in a UHF band of 300 MHz to 3 GHZ, and perform plasma processing on the substrate.

The plasma processing apparatus 100 includes a processing container 1, a lid 2, and a stage 3. The processing container 1 has a cylindrical shape with its bottom centered on an axis Ax and its top opened. The lid 2 is configured to seal an upper opening of the processing container 1. A processing chamber U is disposed in the processing container 1. The stage 3 is located in the processing chamber U, and a substrate W is placed thereon. The substrate W is subjected to plasma processing in the processing chamber U. The substrate W is not particularly limited as long as it is subjected to plasma processing, but examples of the substrate W may include a semiconductor wafer, an insulating substrate such as glass or alumina, a metal substrate and the like. The stage 3 has a disc shape, and its central axis is common to the axis Ax.

The plasma processing apparatus 100 further includes an upper electrode 5 and a dielectric ring 7. The upper electrode 5 faces the stage 3 and is located above the stage 3. The upper electrode 5 has a disc shape, and its central axis is common to the axis Ax. The upper electrode 5 has a metallic shower plate structure.

A space surrounded by the upper electrode 5, the lid 2, and the processing container 1 serves as a waveguide 9. The waveguide 9 is located along the upper electrode 5. Radio-frequency power in the VHF band (hereinafter, referred to as “VHF”) propagates through the waveguide 9. However, radio-frequency power in the UHF band may also propagate through the waveguide 9.

A diffusion chamber 5a and a plurality of gas holes 5b are formed in the upper electrode 5. The plurality of gas holes 5b are through-holes that penetrate a lower surface of the upper electrode 5, allowing the diffusion chamber 5a to be in fluid communication with the processing chamber U. The dielectric ring 7 is an annular member having an inner diameter slightly larger than a diameter of the upper electrode 5 and an outer diameter slightly smaller than a diameter of an inner surface of the processing container 1, and separates the processing chamber U in a vacuum space from the waveguide 9 in an atmospheric space. The dielectric ring 7 is located between the upper electrode 5 and the processing container 1 at an end of the waveguide 9.

The lid 2 has a disc shape, and its center has an opening. A central axis of the lid 2 is common to the axis Ax. A matcher 10 is located at a top of the plasma processing apparatus 100 so as to close the central opening of the lid 2. The matcher 10 is electrically connected to the upper electrode via a transmission line 8. The transmission line 8 may be composed of a waveguide or a coaxial cable capable of transmitting the radio-frequency power in the VHF or UHF band.

The VHF power supply 11 is electrically connected to the upper electrode 5 via the matcher 10 and the transmission line 8. The VHF power supply 11 outputs VHF and supplies the VHF power into the processing container 1. For example, the VHF power supply 11 outputs the VHF with a reference frequency F of 200 MHz and a wavelength 2 of 1.5 m. The VHF power supply 11 may output the VHF with a frequency of 30 MHz to 300 MHz. The matcher 10 includes a matching circuit for matching impedance of a load side (upper electrode 5 side) of the VHF power supply 11 to output impedance of the VHF power supply 11.

The VHF propagates through the waveguide 9 via the matcher 10 and the transmission line 8 and is radiated into the processing chamber U through the dielectric ring 7. As a result, the VHF power for generating plasma is supplied into the processing chamber U. The plasma processing apparatus 100 may supply radio-frequency power in the UHF band, instead of the VHF band, into the processing chamber U.

The plasma processing apparatus 100 further includes a gas supply source 16. The gas supply source 16 is connected to a gas supply pipe 17. The gas supply pipe 17 passes through the lid 2, the waveguide 9, and a part of the upper electrode 5, and is in fluid communication with the diffusion chamber 5a. A process gas is supplied from the gas supply source 16, diffused in the diffusion chamber 5a through the gas supply pipe 17, and then supplied into the processing chamber U through the plurality of gas holes 5b.

In the example shown in FIG. 1, the dielectric ring 7 has the same thickness as the upper electrode 5. However, the thickness of the dielectric ring 7 is not limited thereto, and may be thicker or thinner than the upper electrode 5. The dielectric ring 7 is formed of a dielectric material such as alumina ceramic. The dielectric ring 7 radiates the VHF across the entire circumference from a lower surface of the dielectric ring 7. The dielectric ring 7 functions as a radio-frequency introducer that radiates the VHF into the processing chamber U.

The stage 3 is electrically connected to a radio-frequency power supply 12. The radio-frequency power supply 12 applies a radio-frequency bias voltage in the RF (Radio Frequency) band to the stage 3 in order to attract mainly ions in the plasma.

A gas exhaust port 18 is formed at a bottom of the processing container 1. The gas exhaust port 18 is connected to an exhauster 19. The exhauster 19 exhausts a gas in the processing chamber U to an outside through the gas exhaust port 18.

When a process gas is introduced into the processing container 1 and the VHF is introduced into the processing chamber U in a state where an interior of the processing chamber U is depressurized by the exhauster 19 to a pressure where it is possible to generate plasma, plasma is generated from the process gas in the processing chamber U by the VHF power. The substrate W is processed by the generated plasma.

A controller 20 processes computer executable instructions to be executed by the plasma processing apparatus 100. The controller 20 may be configured to control each element of the plasma processing apparatus 100 to perform various processes. In one embodiment, a part or all of the controller 20 may be included in the plasma processing apparatus 100. The controller 20 may include a processor, a storage, and a communication interface. The controller 20 is realized by, for example, a computer. The processor may be configured to perform various control operations by reading a program from the storage and executing the read program. This program may be stored in the storage in advance, or may be acquired via a medium when necessary. The acquired program is stored in the storage, and is read from the storage and executed by the processor. The medium may be various non-transitory storage media readable by a computer, or may be a communication line connected to the communication interface. The processor may be a CPU (Central Processing Unit). The storage may include a RAM (Random Access Memory), a ROM (Read Only Memory), an HDD (Hard Disk Drive), an SSD (Solid State Drive), or a combination of these. The communication interface communicates with the plasma processing apparatus 100 via a communication line such as a LAN (Local Area Network).

### [Electric Field Sensor]

The plasma processing apparatus 100 includes electric field sensors 14 in contact with the dielectric ring 7 that separates the processing chamber U and the waveguide 9. The plasma processing apparatus 100 includes four or more electric field sensors 14 disposed in a circumferential direction of the dielectric ring 7. The electric field sensors 14 are inserted from an outer surface of the processing container 1 into through-holes penetrating a sidewall of the processing container 1, and their tips abut on or are pressed into an outer surface of the dielectric ring 7. As a result, the electric field sensors 14 are attached to the processing container 1 in a state where the electric field sensors 14 are in contact with the dielectric ring 7. The electric field sensors 14 are provided in positions close to the plasma, and therefore have a heat resistance of 100 degrees C. or higher.

The plasma processing apparatus 100 includes four or more electric field sensors 14. In the example shown in FIG. 2, four electric field sensors 14a, 14b, 14c, and 14d are disposed at intervals of π/6 in the circumferential direction of the dielectric ring 7. Tips of the four electric field sensors 14a, 14b, 14c, and 14d abut on the outer surface of the dielectric ring 7. By disposing the four or more electric field sensors 14 at positions of the dielectric ring 7 in this way, the controller 20 monitors electric field distribution of a standing wave at a location close to plasma load based on sensor values detected by the four or more electric field sensors 14. This allows the controller 20 to accurately monitor a state of the plasma that is generated from the process gas by using the VHF. As a result, it is possible for the plasma processing apparatus 100 to detect deviation of a center of the generated plasma from the axis Ax and shift and loss of effective power of the VHF output from the VHF power supply 11.

Each electric field sensor 14 may be a probe pin with a coaxial structure. The electric field sensor 14 may also be a spring-type probe pin. When the electric field sensor 14 is the spring-type probe pin, a pressing force of the electric field sensor 14 against the dielectric ring 7 may always be kept constant by an elastic force of the spring. This allows the electric field sensor 14 to absorb thermal deformation of the dielectric ring 7 caused by a temperature change and to monitor the electric field distribution of the standing wave at a location close to the plasma load with good sensitivity. The four electric field sensors 14a, 14b, 14c, and 14d are an example of the four or more electric field sensors 14, and the number and positions of the electric field sensors 14 are not limited thereto.

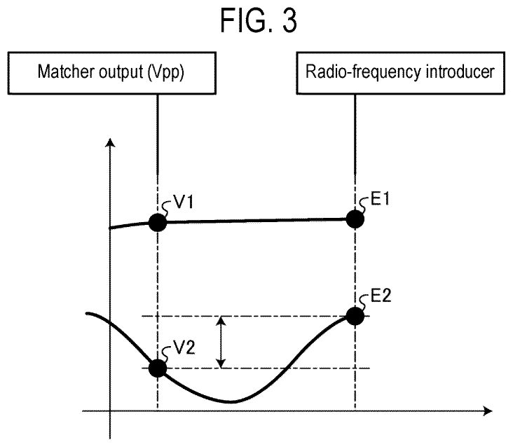

In a conventional plasma processing apparatus, a voltage sensor may be placed at an output of the matcher to monitor a state of plasma in the processing chamber. The voltage sensor monitors a Vpp value indicating a peak-to-peak voltage at the output of the matcher. The present discloser(s) placed a voltage sensor (not shown) at the output of the matcher 10 of the plasma processing apparatus 100 and monitored the state of plasma from the Vpp value and the sensor value of the electric field sensor 14. FIG. 3 is a diagram showing an example of the monitor Vpp value of the voltage sensor placed at the output of the matcher and the sensor value of the electric field sensor 14 installed at the radio-frequency power introducer close to the plasma load. In FIG. 3, V1 is the Vpp value detected by the voltage sensor when plasma is generated from the process gas by using radio-frequency power in the RF band of 13.56 MHz, and E1 is the sensor value detected by the electric field sensor 14 under the same conditions. In FIG. 3, V2 is the Vpp value detected by the voltage sensor when plasma is generated from the process gas by using radio-frequency power in the VHF band of 200 MHz, for example, and E2 is the sensor value detected by the electric field sensor 14 under the same conditions. Further, both the Vpp value and the sensor value are voltage values.

A wavelength of a radio-frequency wave in the RF band of 13.56 MHz is 22 m, while a wavelength of a radio-frequency wave in the VHF band of 200 MHz is 1.5 m. Therefore, since the wavelength of the radio-frequency wave of 13.56 MHz is relatively long, a phase of the radio-frequency wave of 13.56 MHz hardly changes with a distance from the output of the matcher 10 to the dielectric ring 7, which is the introducer of the radio-frequency power into the processing chamber U. Therefore, there is almost no difference between the Vpp value V1 and the sensor value E1. As a result, when plasma is generated from the process gas by using the radio-frequency power in the RF band of 13.56 MHz or the like, it is possible to detect how much voltage is being supplied to the introducer by monitoring the Vpp value.

In contrast, for example, since the wavelength of 200 MHz VHF is relatively short, a phase of the 200 MHz VHF changes with the distance from the output of the matcher 10 to the dielectric ring 7. Therefore, a difference occurs between the Vpp value V2 and the sensor value E2. As a result, when plasma is generated from the process gas by using the radio-frequency power in the VHF band of 200 MHz or the like, it is not possible to obtain a correlation between the Vpp value and the voltage supplied to the introducer and, therefore, it is not possible to accurately determine the state of plasma from the Vpp value.

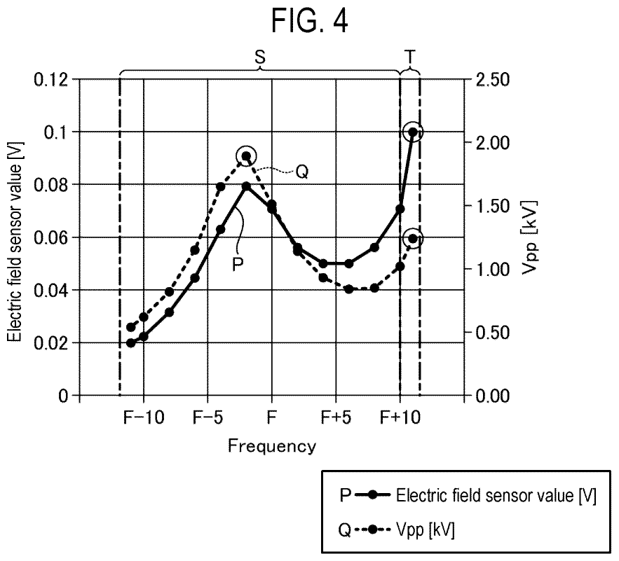

FIG. 4 is a diagram showing an example of the Vpp value and the sensor value of the electric field sensor 14 for each frequency when a variable frequency power supply is used as the VHF power supply 11. The horizontal axis of FIG. 4 indicates a frequency of the radio-frequency power used to generate plasma. At this time, a reference frequency of the radio-frequency power is set to F, and each frequency is indicated by a difference from the reference frequency. The left vertical axis of FIG. 4 indicates the sensor value detected by the electric field sensor 14. The right vertical axis indicates the Vpp value detected by the voltage sensor in the matcher 10. A region S indicates a frequency domain of the radio-frequency power where plasma does not ignite, and a region T indicates a frequency domain of the radio-frequency power where plasma ignites. As shown in FIG. 4, in the plasma processing apparatus 100, plasma does not ignite and is not generated with the radio-frequency power with a frequency having a difference of +10 MHz or less from the reference frequency F. Plasma ignites and is generated with the radio-frequency power with a frequency having a difference of more than +10 MHz from the reference frequency F.

The Vpp value and the sensor value of the electric field sensor 14 indicate that the larger the value, the easier it is for plasma to ignite. In FIG. 4, a line P indicates the sensor value of the electric field sensor 14 at each frequency, and a line Q indicates the Vpp value at each frequency. Further, both the Vpp value and the sensor value are voltage values. As shown by the lines P and Q, overall patterns of the Vpp value and the sensor value of the electric field sensor 14 at each frequency of the radio-frequency power are the same, but there is a deviation in the values on a side of higher frequency, which indicates that a difference in the measurement positions has an effect.

Specifically, the sensor value of the electric field sensor 14 indicated by the line P has a peak value in the region T where plasma ignites. In other words, there is a correlation between the sensor value of the electric field sensor 14 and a frequency band where plasma ignites. In contrast, the Vpp value indicated by the line Q has a peak value in the region S where plasma does not ignite. In other words, there is no correlation between the Vpp value and the frequency band where plasma ignites.

From the above, when the radio-frequency power in the VHF band or higher is supplied, it is difficult to accurately determine the state of plasma, including ease of plasma ignition or the like, from the Vpp value, and it is expected that a deviation occurs between the Vpp value and a process result. Therefore, the plasma processing apparatus 100 uses the sensor values of the four or more electric field sensors 14 located in the circumferential direction of the dielectric ring 7 to monitor the electric field (voltage) distribution of the standing wave at a location close to the plasma load. This allows the plasma processing apparatus 100 to monitor the state of plasma with high accuracy. As a result, it is possible for the plasma processing apparatus 100 to obtain correct process results and detect abnormalities in the apparatus such as damage to parts.

For example, when VHF power of 500 W is input from the VHF power supply 11 into the processing chamber U, plasma is generated according to the power of 500 W. However, if a part of the plasma processing apparatus 100 is damaged or abnormal discharge occurs in the waveguide 9, the VHF power is lost before being input into the processing chamber U. For example, if a loss of the VHF power is 200 W, plasma is generated according to power of 300 W, which is the input 500 W minus the loss of 200 W. In this case, it is possible for the plasma processing apparatus 100 to determine the shift in the effective power of the VHF power from a change in the electric field distribution of the standing wave detected by the electric field sensor 14 at a location close to the plasma load. This allows the plasma processing apparatus 100 to detect abnormalities in the apparatus such as the loss of VHF power.

### [VHF Electric Field Distribution]

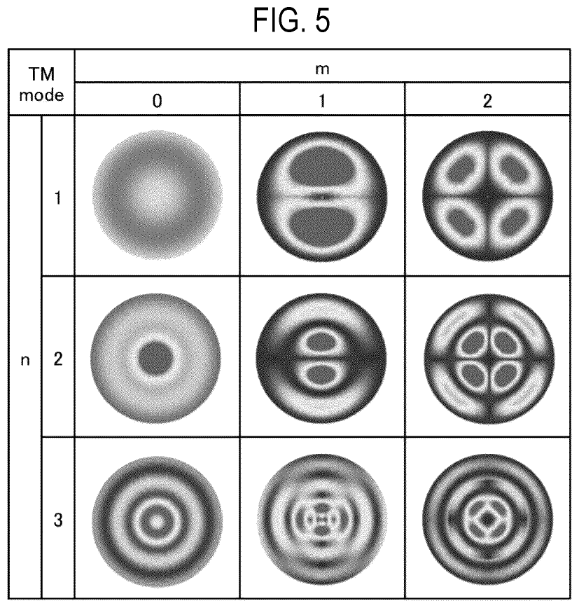

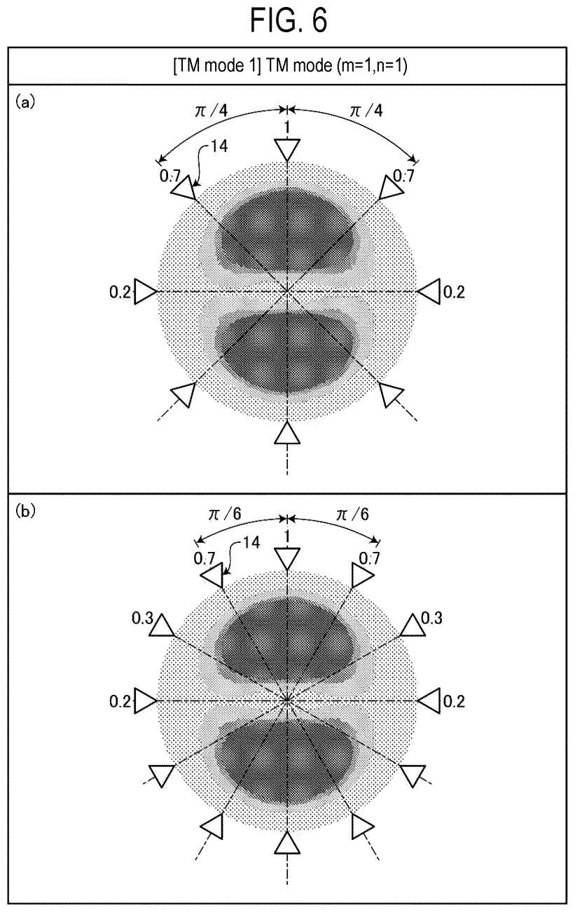

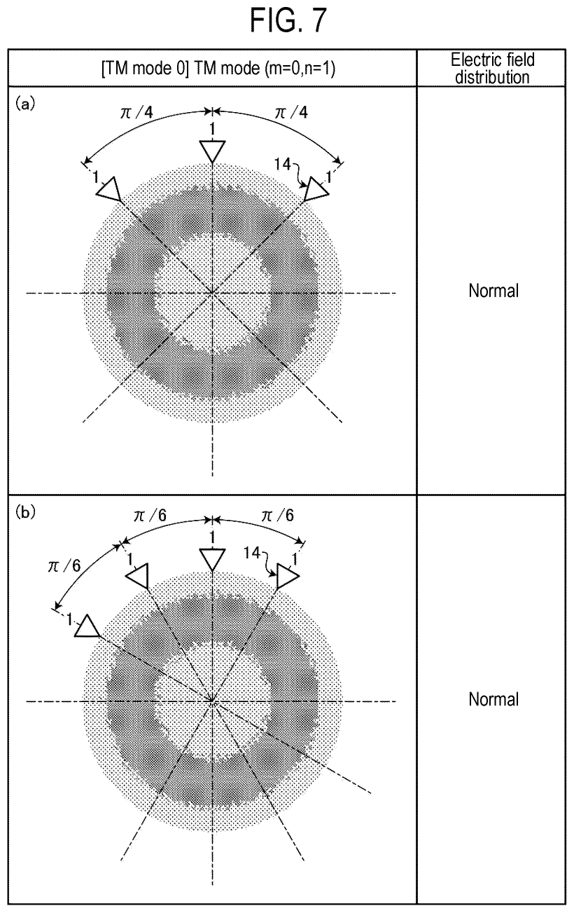

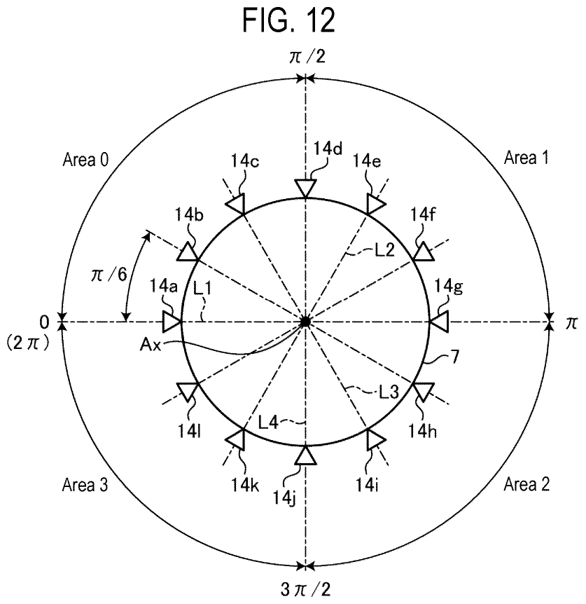

An electric field pattern of the standing wave detected by the electric field sensor 14 is described with reference to FIGS. 5 to 12. FIG. 5 is a diagram showing an example of an electric field pattern for each TM mode directly below the upper electrode 5. FIG. 6 is a diagram showing an example of circumferential disposition of the electric field sensor 14. FIGS. 7 to 11 are diagrams showing examples of the sensor values of the electric field sensor in each TM mode. FIG. 12 is a diagram for explaining an example of circumferential disposition of the electric field sensor 14.

As described above, the plasma processing apparatus 100 disposes the four or more electric field sensors 14 in the circumferential direction of the dielectric ring 7 close to the plasma load so that monitoring accuracy does not decrease depending on the distance from the output of the matcher 10 to the dielectric ring 7, which is the introducer of the VHF power. The tip of each electric field sensor 14 contacts the dielectric ring 7.

The plasma processing apparatus 100 searches for a plasma ignition area based on the sensor values of the four or more electric field sensors 14 by using the controller 20, and accurately determines the state of plasma. The four or more electric field sensors 14 detect the electric field of the standing wave propagating through the dielectric ring 7. The controller 20 receives the sensor values, which are detected by the four or more electric field sensors 14 at the dielectric ring 7, through the communication interface.

Then, the controller 20 monitors the state of plasma, such as plasma electric field distribution and plasma intensity, based on differences among the sensor values of the four or more electric field sensors 14. This allows the controller 20 to detect a shift in effective power input to the plasma, damage to parts of the apparatus, abnormal discharge within the apparatus, a shift in a center position of the plasma, an in-plane distribution of the plasma, etc.

The electric field pattern for each TM mode illustrated in FIG. 5 shows the electric field distribution of the standing wave directly below the upper electrode 5 for each TM mode. There is an electric field pattern that occurs in the standing wave for each TM mode indicated by TM(m, n: m=0 to 2, n=1 to 3). TM(0,1), TM(1,1), and TM(2,1) are also referred to as TM mode 0, TM mode 1, and TM mode 2, respectively. In FIG. 5, when m=1 and 2, the electric field pattern is written as being symmetrical with respect to a horizontal axis or a vertical axis, but the same TM mode may generate an electric field pattern at a position rotated in a peripheral direction.

In the VHF, the electric field distribution changes significantly when the TM mode changes. The TM modes of columns where m is 1 and 2 have a non-uniform electric field distribution in the circumferential direction. Therefore, in the TM modes of columns where m is 1 and 2, except for TM(2,3), it is possible to determine the electric field distribution in a circumferential direction of the plasma in each TM mode by the differences among the sensor values of four or more electric field sensors 14 disposed in the circumferential direction on the outer surface of the dielectric ring 7.

The TM mode of a column where m is 0 has a uniform electric field distribution in the peripheral direction (also referred to as a circumferential direction below). That is, the TM mode of the column where m is 0 has the same electric field in the circumferential direction, but different electric fields in a radial direction. Therefore, in the TM mode of the column where m is 0, it is not possible for the four or more electric field sensors 14 disposed in the circumferential direction to determine the electric field distribution in the radial direction of the plasma generated in each TM mode. In this case, as described later, a concentric electric field distribution of the standing wave in each TM mode may be detected by differences among sensor values of three or more electric field sensors 14 disposed in a vertical direction on the outer surface of the dielectric ring 7. Similarly, for TM(2, 3), since the electric field in the circumferential direction is almost the same, the concentric electric field distribution of the standing wave may be detected by the differences among the sensor values of three or more electric field sensors 14 disposed in the vertical direction.

The present discloser(s) has confirmed that there is a correlation between the electric field distribution detected from the sensor values of the electric field sensors 14 and a thickness of a film formed when the plasma is generated by supplying the process gas in the plasma processing apparatus 100 and the film is formed. From the above, it is considered that there is a correlation between the electric field distribution detected from the sensor values of the electric field sensors 14 and the process result. Therefore, when the differences among the sensor values of the electric field sensors 14 indicate an electric field distribution of TM mode 0 with almost no bias in the electric field distribution in the circumferential and radial directions, the plasma processing apparatus 100 may determine by the controller 20 that the state of plasma is normal. On the other hand, when the differences among the sensor values of the electric field sensors 14 indicate an electric field distribution other than TM mode 0, the plasma processing apparatus 100 may determine by the controller 20 that the state of plasma is abnormal. In the case where the state of plasma is determined to be abnormal, it is not possible to use the mode as a process condition, and the plasma processing apparatus 100 may perform control such that the controller 20 stops the output of the VHF.

FIG. 6 shows the electric field distribution in TM mode 1. In FIGS. 6 to 12, the electric field sensor 14 is shown as a triangle (Δ). In FIG. 6, (a) shows the electric field sensors 14 disposed in the circumferential direction at equal intervals of π/4. An electric field (voltage) indicated by the sensor value detected by the reference electric field sensor 14 disposed at a boundary between first and second quadrants is normalized to 1. At this time, electric fields detected by the five electric field sensors 14 disposed in the first and second quadrants are expressed as 0.2, 0.7, 1, 0.7, and 0.2, with the reference electric field sensor 14 at the center.

In FIG. 6, (b) shows the electric field sensors 14 disposed in the circumferential direction at equal intervals of π/6. An electric field indicated by the sensor value detected by the reference electric field sensor 14 disposed at the boundary between the first and second quadrants is normalized to 1. At this time, electric fields detected by the seven electric field sensors 14 disposed in the first and second quadrants are expressed as 0.2, 0.3, 0.7, 1, 0.7, 0.3, and 0.2, with the reference electric field sensor 14 at the center. Although not shown in (a) and (b) of FIG. 6, electric field sensors 14 in the third and fourth quadrants show approximately the same electric field as the opposing electric field sensors 14 in the first and second quadrants.

FIG. 7 shows the electric field distribution in TM mode 0. In FIG. 7, (a) shows the electric field sensors 14 disposed in the circumferential direction at equal intervals of π/4. When an electric field indicated by the sensor value detected by the reference electric field sensor 14 is normalized to 1, electric fields detected by the three electric field sensors 14 disposed in the first and second quadrants are expressed as 1, 1, and 1. At this time, the controller 20 may predict that the state of plasma is TM mode 0 and determine that the state of plasma is normal.

In FIG. 7, (b) shows the electric field sensors 14 disposed in the circumferential direction at equal intervals of π/6. When an electric field detected by the reference electric field sensor 14 is normalized to 1, electric fields indicated by the sensor values detected by the four electric field sensors 14 disposed in the first and second quadrants are expressed as 1, 1, 1, and 1. At this time, the controller 20 may predict that the state of plasma is TM mode 0 and determine that the state of plasma is normal.

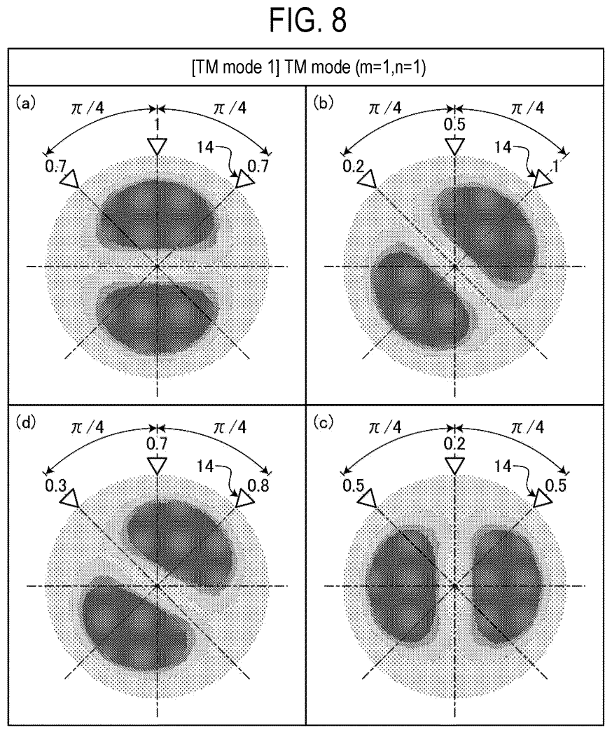

FIG. 8 shows the electric field distribution in TM mode 1. In TM mode 1, plasma distribution occurs every x. In FIG. 8, (a) to (d) show three electric field sensors 14 disposed in the circumferential direction at equal intervals of π/4. The electric field distributions in (b) to (d) of FIG. 8 show states rotated by about 45°, 90°, and 30° clockwise with respect to the electric field distribution in (a) of FIG. 8. In FIG. 8, (a) to (d) show electric fields indicated by the sensor values detected by the three electric field sensors 14 as numerical values, assuming that an electric field detected by the reference electric field sensor 14 is 1. The numerical values are 0.7, 1, and 0.7 in (a) of FIG. 8, 1, 0.5, and 0.2 in (b) of FIG. 8, 0.5, 0.2, and 0.5 in (c) of FIG. 8, and 0.8, 0.7, and 0.3 in (d) of FIG. 8, counterclockwise. According to this, when the three electric field sensors 14 are disposed in the circumferential direction at equal intervals of π/4, the differences among the three sensor values are large, and it is possible to detect the electric field distribution in the circumferential direction. This allows the controller 20 to determine abnormalities in the state of plasma.

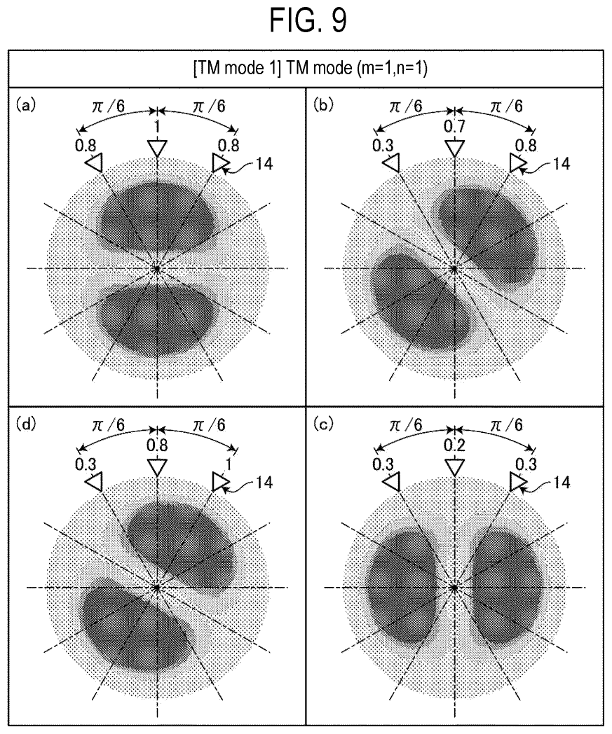

However, as shown in FIG. 9, the intervals at which the electric field sensors 14 are disposed are changed, and the three electric field sensors 14 are disposed in the circumferential direction at equal intervals of π/6. In this case, the numerical values of the electric fields indicated by the sensor values are 0.8, 1, and 0.8 in (a) of FIG. 9, 0.8, 0.7, and 0.3 in (b) of FIG. 9, 0.3, 0.2, and 0.3 in (c) of FIG. 9, and 1, 0.8, and 0.3 in (d) of FIG. 9, counterclockwise. According to this, when the three electric field sensors 14 are disposed in the circumferential direction at equal intervals of π/6, the differences among the three sensor values may be small, and it may be difficult for the controller 20 to detect a difference in the electric field distribution in the circumferential direction. As a result, the controller 20 may not be able to determine abnormalities in the state of plasma.

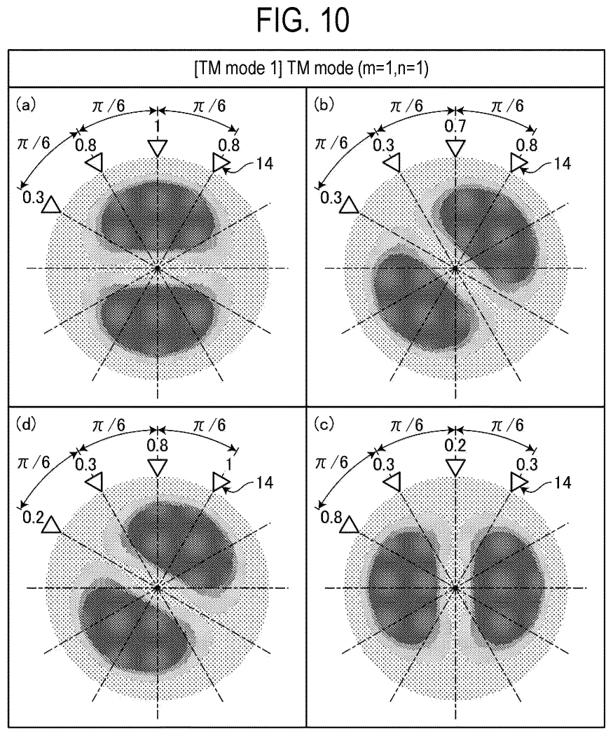

Therefore, as shown in FIG. 10, the number of electric field sensors 14 is changed, and four electric field sensors 14 are disposed in the circumferential direction at equal intervals of π/6. In this case, the numerical values of the electric fields are 0.8, 1, 0.8, and 0.3 in (a) of FIG. 10, 0.8, 0.7, 0.3, and 0.3 in (b) of FIG. 10, 0.3, 0.2, 0.3, and 0.8 in (c) of FIG. 10, and 1, 0.8, 0.3, and 0.2 in (d) of FIG. 10, counterclockwise. According to this, when the four electric field sensors 14 are disposed in the circumferential direction at equal intervals of π/6, it is possible for the controller 20 to detect the electric field distribution in the circumferential direction from the large differences among the four sensor values. This allows the controller 20 to determine abnormalities in the state of plasma.

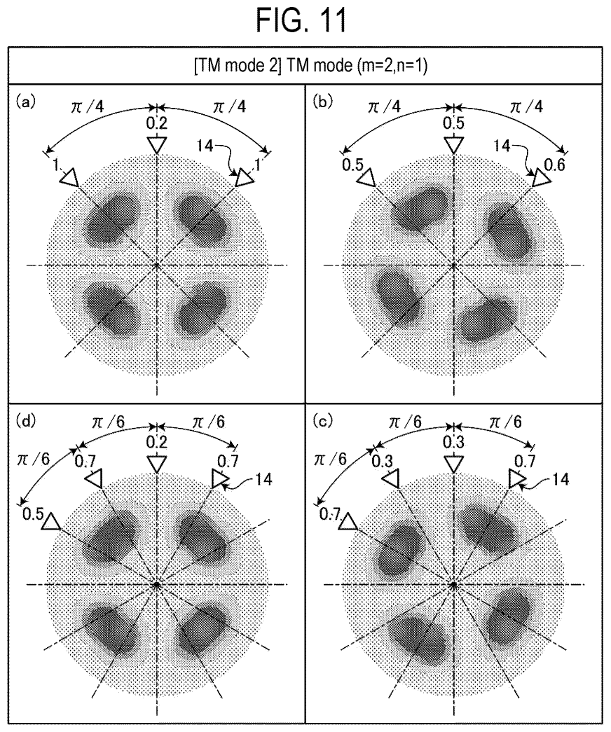

FIG. 11 shows the electric field distribution in TM mode 2. In TM mode 2, the plasma mode occurs every π/2. In FIG. 11, (a) and (b) show three electric field sensors 14 disposed in the circumferential direction at equal intervals of π/4. In FIG. 11, (c) and (d) show four electric field sensors 14 disposed in the circumferential direction at equal intervals of π/6. The electric field distributions in (b) and (d) of FIG. 11 show states rotated by several tens of degrees clockwise with respect to the electric field distributions in (a) and (c) of FIG. 11, respectively. In this case, the numerical values of the electric fields indicated by the sensor values are 1, 0.2, and 1 in (a) of FIG. 11, 0.6, 0.5, and 0.5 in (b) of FIG. 11, 0.7, 0.3, 0.3, and 0.7 in (c) of FIG. 11, and 0.7, 0.2, 0.7, and 0.5 in (d) of FIG. 11, counterclockwise.

According to this, when the three electric field sensors 14 are disposed in the circumferential direction at equal intervals of π/4, there may be no differences among the three sensor values, and it is difficult for the controller 20 to detect the electric field distribution in the circumferential direction. As a result, the controller 20 may not be able to determine abnormalities in the state of plasma. On the other hand, when the four electric field sensors 14 are disposed in the circumferential direction at equal intervals of π/6, it is possible for the controller 20 to detect the electric field distribution in the circumferential direction from the large differences among the four sensor values. This allows the controller 20 to determine abnormalities in the state of plasma.

The number of electric field sensors 14 located in the circumferential direction of the dielectric ring 7 may be four or more. The four or more electric field sensors are disposed at positions where an angle between a straight line connecting a center of the dielectric ring 7 and one of the four or more electric field sensors 14 and a straight line connecting the center of the dielectric ring 7 and each of the four or more electric field sensors is represented by 0, (t₁·π/2+π/6), (t₂·π/2+2π/6), and (t₃·π/2+3π/6), when a reference position is 0.

The circumferential disposition of the four electric field sensors 14 is further described with reference to FIG. 12. FIG. 12 is a diagram for explaining an example of the circumferential disposition of the four electric field sensors 14. As shown in FIG. 5, TM mode 0 has a uniform concentric electric field pattern in the circumferential direction, TM mode 1 has the same electric field pattern every x in the circumferential direction, and TM mode 2 has the same electric field pattern every π/2 in the circumferential direction. Therefore, in TM modes 0 to 2, the minimum unit at which an electric field pattern appears in the circumferential direction is π/2. Therefore, as shown in FIG. 12, the circumferential direction of the dielectric ring 7 is divided into areas 0, 1, 2, and 3 every π/2. In the circumferential direction, it is possible to dispose the electric field sensors 14a to 141 at intervals of π/6. A method of determining the positions of the four electric field sensors 14 that monitor the electric field of the standing wave propagating through the dielectric ring 7 from among the electric field sensors 14a to 141 is described.

Herein, for convenience of explanation, one of the four electric field sensors 14 is designated as the electric field sensor 14a. In addition, a straight line connecting the center (hereinafter, indicated as an “axis Ax”) of the dielectric ring 7 and the electric field sensor 14a is indicated as a straight line L1. The four electric field sensors 14 are disposed at positions where angles formed by the straight line L1 shown in FIG. 12 and straight lines L1, L2, L3, and L4 connecting the axis Ax and each of the four electric field sensors 14 are indicated as 0, (t₁·π2/+π/6), (t₂·π2/+2π/6), and (t₃·π2/+3π/6).

t₁, t₂, and t₃ are integers including 0. t₁, t₂, and t₃ indicate areas in which four or more electric field sensors 14 are disposed among the areas every π/2. π/6, 2π/6, and 3π/6 indicate positions in which the area defined by t₁, t₂, and t₃ is divided every π/6. When t₁, t₂, and t₃ are 0, the four electric field sensors 14 are located in the circumferential direction at intervals of π/6 in area 0 where the angle between the straight line L1 and each of the straight lines L1, L2, L3, and L4 is 0 to π/2. In the example of FIG. 12, four electric field sensors 14a to 14d are disposed in area 0. In this way, four or more electric field sensors 14 may be located in the circumferential direction in any of four areas 0 to 3, from 0 to π/2, from π/2 to π, from π to 3π/2, and from 3π/2 to 2π, respectively.

When at least one of t₁, t₂, and t₃ is 1 or more, the four electric field sensors 14 are located in the circumferential direction such that the angles formed by the straight line L1 and each of the straight lines L1, L2, L3, and L4 are distributed among two or more of the four areas 0 to 3. For example, when t₁ is 1 and t₂ and t₃ are 2, the four electric field sensors 14 are disposed at positions where the angles formed by the straight line L1 and the straight lines L1, L2, L3, and L4 shown in FIG. 12 are 0, (π/2+π/6), (π+2π/6), and (π+3π/6). In the example of FIG. 12, the four electric field sensors 14a, 14e, 14i, and 14j are disposed. In this way, four or more electric field sensors 14 may be located in the circumferential direction and distributed among two or more of the four areas 0 to 3.

### Effects of First Embodiment

The four or more electric field sensors 14 are also disposed in the circumferential direction of the dielectric ring 7 at the positions described so far. This allows the controller 20 to detect a bias in the circumferential electric field distribution of the standing wave close to the plasma load from the differences among the sensor values monitored by the four or more electric field sensors 14. This makes it possible to detect circumferential deviations in plasma distribution, circumferential deviations in plasma input power, and the like.

For example, if the differences among the sensor values of the four or more electric field sensors 14 indicate an electric field distribution of TM mode 0 with almost no bias in the circumferential electric field distribution, the controller 20 may determine that the plasma distribution is generated almost uniformly and that the state of plasma is normal. On the other hand, if the differences among the sensor values of the four or more electric field sensors 14 indicate an electric field distribution other than TM mode 0, the controller 20 may determine that the plasma distribution is non-uniform and that the state of plasma is abnormal. In this way, it is possible for the controller 20 to determine whether the state of plasma is normal or abnormal based on the differences among the sensor values of the four or more electric field sensors 14. If the state of plasma is determined to be abnormal, the controller 20 may perform control to stop the process, for example, by stopping the VHF output.

In addition, it is possible for the controller 20 to detect a bias in the circumferential electric field distribution of the substrate W facing the upper electrode 5 based on the sensor values detected by the four or more electric field sensors 14 in the circumferential direction of the dielectric ring 7.

In addition, it is possible for the controller 20 to detect a bias in a bias voltage applied to the disc-shaped stage 3, which shares the axis Ax with the dielectric ring 7, based on the sensor values detected by the four or more electric field sensors 14 in the circumferential direction of the dielectric ring 7. This makes it possible to determine whether or not there is plasma instability due to excessive application of the bias voltage.

### Second Embodiment

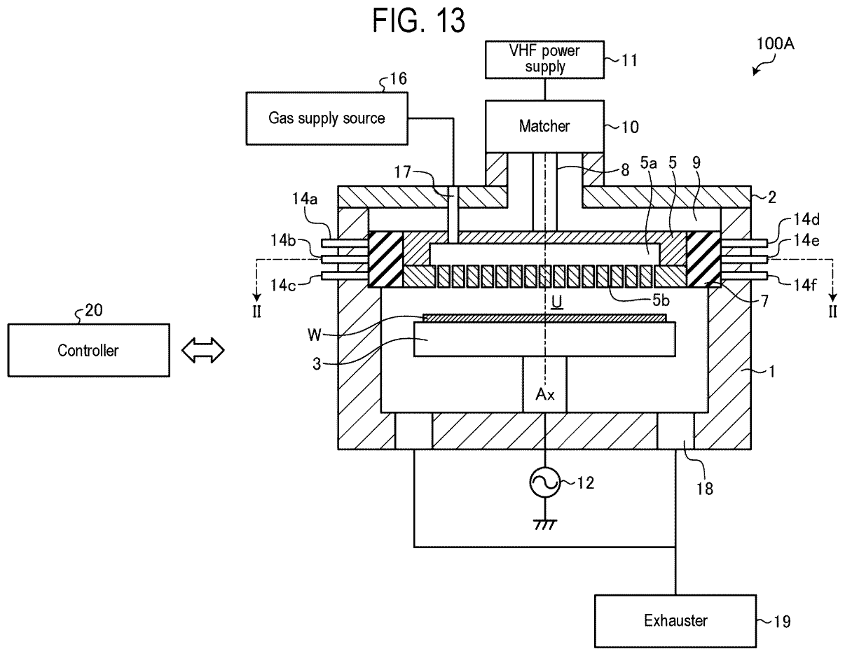

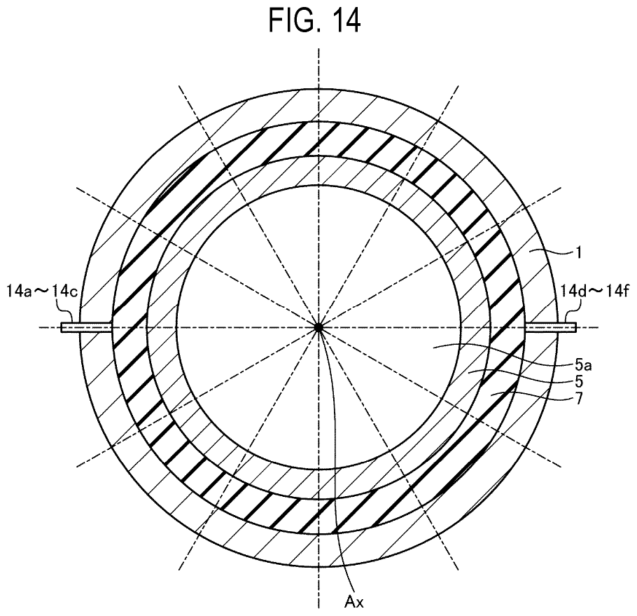

Next, a plasma processing apparatus according to a second embodiment of the present disclosure is described with reference to FIGS. 13 and 14. FIG. 13 is a schematic cross-sectional view showing an example of the plasma processing apparatus according to the second embodiment. FIG. 14 is a cross-sectional view taken along line II-II in FIG. 13.

In the plasma processing apparatus 100A according to the second embodiment, three or more electric field sensors 14 are located along a propagation direction of the VHF propagating through the dielectric ring 7, and are disposed within an area of ¼ of an effective wavelength Neff of the VHF. The rest of the configuration of the plasma processing apparatus 100A is the same as that of the plasma processing apparatus 100 according to the first embodiment. Therefore, for the plasma processing apparatus 100A, the disposition of the electric field sensors 14 is described, and description of the other configurations is omitted.

In the plasma processing apparatus 100A, the three or more electric field sensors 14 are disposed along the propagation direction of the VHF propagating through the dielectric ring 7. In the example of FIG. 13, the propagation direction of the VHF propagating through the dielectric ring 7 is the vertical direction (thickness direction) of the dielectric ring 7, and the three or more electric field sensors 14 are each disposed within the area of ¼ of the effective wavelength λ_{eff} of the VHF in the vertical direction of the dielectric ring 7. If a relative dielectric constant of the dielectric ring 7 is Er and a free space wavelength is λ, the effective wavelength λ_{eff} of the VHF is expressed by the following equation.

$${λ}_{eff} = λ / √ {ε}_{r}$$

In the example of FIGS. 13 and 14, the three electric field sensors 14a, 14b, and 14c are disposed at a same position in the circumferential direction of the dielectric ring 7, and are disposed in the vertical direction of the dielectric ring 7 in order from top to bottom. In addition, the three electric field sensors 14d, 14e, and 14f are disposed at a same position in the circumferential direction of the dielectric ring 7, and are disposed in the vertical direction of the dielectric ring 7 in order from top to bottom. The electric field sensor 14a and the electric field sensor 14d are located opposite to each other in the circumferential direction. The electric field sensor 14b and the electric field sensor 14e are located opposite to each other in the circumferential direction. The electric field sensor 14c and the electric field sensor 14f are located opposite to each other in the circumferential direction.

The electric field sensors 14a to 14f are inserted from the outer surface of the processing container 1 into through-holes penetrating the sidewall of the processing container 1, and are attached to the dielectric ring 7 so that their tips abut against or are pressed into the outer surface of dielectric ring 7. The electric field sensors 14a to 14c contact the dielectric ring 7 from a same direction. Similarly, the electric field sensors 14d to 14f contact the dielectric ring 7 from a same direction. Since the electric field sensors 14 are provided in positions close to plasma, they have a heat resistance of 100 degrees C. or more.

The TM mode of the column where m is 0 as illustrated in FIG. 5 has a uniform concentric electric field distribution. Therefore, it is not possible to detect the concentric electric field distribution of the standing wave from the differences among the sensor values of four or more electric field sensors 14 disposed in the circumferential direction with respect to the outer surface of the dielectric ring 7. Therefore, in the plasma processing apparatus 100A, three or more electric field sensors 14 are disposed in the vertical direction with respect to the outer surface of the dielectric ring 7 within the area of ¼ of the effective wavelength λ_{eff} of the VHF.

When the three or more electric field sensors 14 disposed in the vertical direction detect the electric field (voltage) at positions disposed within the area of ¼ of the effective wavelength Neff of the VHF, the controller 20 is allowed to estimate the electric field distribution of one wavelength of the VHF. This allows the controller 20 to detect the concentric electric field distribution of the standing wave from the differences among the sensor values of the three or more electric field sensors 14 disposed in the vertical direction. This allows the controller 20 to determine one of TM mode 0 (TM(0,1)), TM(0,2), and TM(0,3), which are concentric distributions.

For example, an example of TM mode determination is described assuming that the three electric field sensors 14a, 14b, and 14c output sensor values that respectively project an electric field at a center, a middle between the center and a periphery, and the periphery of the concentric distribution of TM mode. When the sensor values detected by the electric field sensors 14a, 14b, and 14c are 0.7, 1, and 1, respectively, the controller 20 is able to detect that the electric field distribution is TM mode 0 based on the differences among the sensor values. When the sensor values detected by the electric field sensors 14a, 14b, and 14c are 0.8, 0.3, and 0.5, respectively, the controller 20 is able to detect that the electric field distribution is TM(0, 2) based on the differences among the sensor values. When the sensor values detected by the electric field sensors 14a, 14b, and 14c are 0.8, 0.4, and 0.2, respectively, the controller 20 is able to detect that the electric field distribution is TM(0, 3) based on the differences among the sensor values. Further, the sensor values described herein are merely examples and are not limited thereto.

When the differences among the sensor values of the electric field sensors 14 indicate the electric field distribution of TM mode 0, the controller 20 is able to determine that the state of plasma is normal. On the other hand, when the differences among the sensor values of the electric field sensors 14 indicate an electric field distribution other than TM mode 0, the controller 20 is able to determine that the state of plasma is abnormal. If the state of plasma is determined to be abnormal, the controller 20 may perform control to stop the process by stopping the VHF output.

However, it is sufficient that three or more electric field sensors 14 are disposed in the vertical direction. When the three electric field sensors 14a, 14b, and 14c are disposed in the vertical direction, the electric field sensors 14d, 14e, and 14f do not need to be disposed.

As shown in FIG. 13, when the electric field sensors 14a to 14c and the electric field sensors 14d to 14f are disposed in 3:3 pairs, the controller 20 detects the concentric electric field distribution of the standing wave from the differences among the sensor values of the electric field sensors 14a to 14c disposed in the vertical direction. The controller 20 also detects the concentric electric field distribution of the standing wave from the differences among the sensor values of the electric field sensors 14d to 14f disposed in the vertical direction. This allows the controller 20 to detect a bias of an electric field distribution in a radial direction of the substrate W from the sensor values output from the three or more electric field sensors 14. In addition, it is possible to detect the electric field distribution in the circumferential direction by at least one selected from the group of combination of the electric field sensor 14a and the electric field sensor 14d, the electric field sensor 14b and the electric field sensor 14e, and the electric field sensor 14c and the electric field sensor 14f.

The electric field sensors 14a to 14c and any of the electric field sensors 14d to 14f may be disposed in a 3:1 ratio. In this case, the controller 20 detects the concentric electric field distribution of the standing wave from the differences among the sensor values of the electric field sensors 14a to 14c. In addition, the controller 20 detects the electric field distribution in the circumferential direction of the standing wave by the electric field sensor 14c and the electric field sensor 14f.

For example, in a case where the sensor values detected by the electric field sensor 14c and the electric field sensor 14f are assumed to be 0.5 and 0.9, and a preset threshold value indicating a bias of the electric field distribution is 0.2, the controller 20 may determine that the plasma is biased due to a tilt of the stage 3 since the difference between these sensor values is equal to or greater than the threshold value.

In this way, the plasma processing apparatus 100A may further include an electric field sensor 14 in the circumferential direction corresponding to at least one selected from the group of the three or more electric field sensors 14 disposed in the vertical direction. The controller 20 is able to detect, for example, a tilt of the stage 3 based on the sensor values output from the electric field sensors 14 located in the circumferential direction. If the stage 3 is tilted, a spread of the plasma changes by the bias voltage applied to the stage 3. If the sensor value detected by the electric field sensor 14f is greater than that of the electric field sensor 14c, the plasma intensity is stronger on a side of the electric field sensor 14f than on a side of the electric field sensor 14c. Therefore, the controller 20 may determine that the tilt of the stage 3 causes the plasma intensity to vary, and that the plasma is biased.

### Effects of Second Embodiment

In this way, it is possible for the plasma processing apparatus 100A to detect the concentric electric field distribution of the standing wave by using the three or more electric field sensors 14 in the vertical direction. Further, it is possible for the plasma processing apparatus 100A to detect a tilt of the stage 3 and a bias in the plasma by disposing the electric field sensors 14 in the circumferential direction so as to correspond to at least one selected from the group of the three or more electric field sensors 14 in the vertical direction.

Further, the plasma processing apparatus 100A may dispose three or more electric field sensors 14 in the circumferential direction so as to correspond to at least one selected from the group of the three or more electric field sensors 14 in the vertical direction. As a result, the plasma processing apparatus 100A may achieve the effects of the first embodiment and the second embodiment by having three or more electric field sensors 14 in the vertical direction and four or more electric field sensors 14 in the circumferential direction.

### Third Embodiment

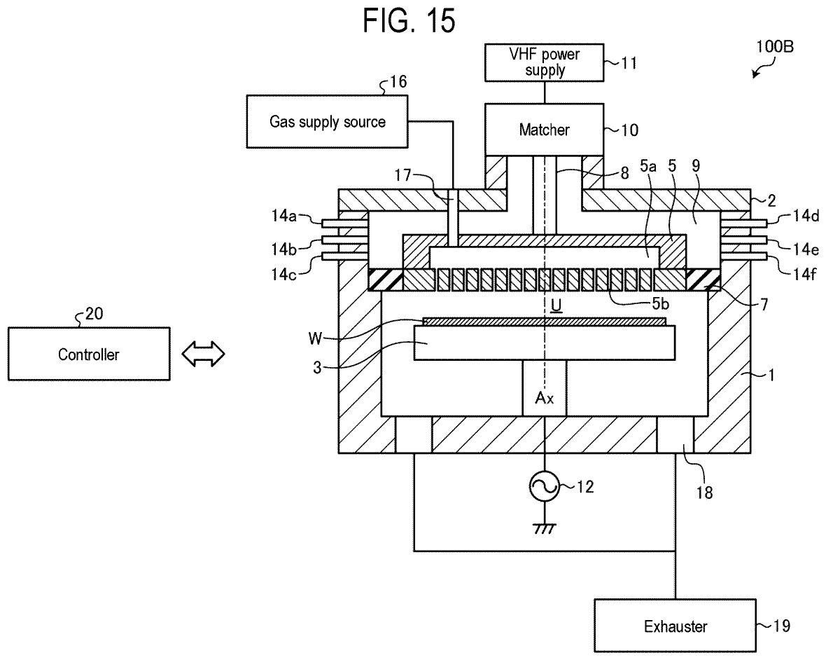

Next, a plasma processing apparatus according to a third embodiment of the present disclosure is described with reference to FIG. 15. FIG. 15 is a schematic cross-sectional view showing an example of the plasma processing apparatus according to the third embodiment.

In the plasma processing apparatus 100B according to the third embodiment, three or more electric field sensors 14 are located along a propagation direction of the VHF propagating through the waveguide 9, and are disposed within an area of ¼ of the effective wavelength Neff of the VHF. The rest of the configuration of the plasma processing apparatus 100B is the same as that of the plasma processing apparatus 100A according to the second embodiment. Therefore, for the plasma processing apparatus 100B, the disposition of the electric field sensors 14 is described, and description of the other configurations is omitted.

In the plasma processing apparatus 100B, the three or more electric field sensors 14 are disposed in the propagation direction of the VHF propagating through the waveguide 9. In the example of FIG. 15, the propagation direction of the VHF propagating through the waveguide 9 is along the sidewall of the processing container 1, and the three electric field sensors 14a to 14c are each disposed within the area of ¼ of the effective wavelength Neff of the VHF along the sidewall of the processing container 1.

The three electric field sensors 14a, 14b, and 14c are disposed at a same position in a circumferential direction of the inner surface of the processing container 1, and are disposed in the vertical direction on the sidewall of the processing container 1 in order from top to bottom. In addition, the three electric field sensors 14d, 14e, and 14f are disposed at a same position in the circumferential direction of the inner surface of the processing container 1, and are disposed in the vertical direction on the sidewall of the processing container 1 in order from top to bottom. The electric field sensor 14a and the electric field sensor 14d are located opposite to each other in the circumferential direction. The electric field sensor 14b and the electric field sensor 14e are located opposite to each other in the circumferential direction. The electric field sensor 14c and the electric field sensor 14f are located opposite to each other in the circumferential direction.

The three electric field sensors 14a, 14b, and 14c are inserted into through-holes penetrating the sidewall of the processing container 1 from the outer surface of the processing container 1, and are attached so that their tips are located along the inner surface of the processing container 1 and are exposed to the waveguide 9. The electric field sensors 14a to 14c are exposed to the waveguide 9 from a same direction. Similarly, the electric field sensors 14d to 14f are attached so that they are exposed to the waveguide 9 from a same direction. The electric field sensors 14 are provided in positions close to the plasma, and therefore have a heat resistance of 100 degrees C. or more. The electric field sensors 14 detect the electric field of the standing wave on a surface of the waveguide 9.

### Effects of Third Embodiment

In this way, it is possible for the plasma processing apparatus 100B to detect the concentric electric field distribution of the standing wave propagating through the dielectric ring 7 by using the three or more electric field sensors 14 in the vertical direction. Further, it is possible for the plasma processing apparatus 100B to detect a tilt of the stage 3 and a bias in the plasma by disposing the electric field sensors 14 in the circumferential direction so as to correspond to at least one selected from the group of the three or more electric field sensors 14 in the vertical direction.

In addition, in the plasma processing apparatus 100B, if the dielectric ring 7 does not have a thickness to mount three or more electric field sensors 14 in the vertical direction within the area of ¼ of the effective wavelength Neff of the VHF, the three or more electric field sensors 14 may be mounted on the waveguide 9 adjacent to the dielectric ring 7. This makes it possible to detect the concentric electric field distribution of the standing wave propagating through the waveguide 9.

Further, by using a combination of four or more electric field sensors 14 in the circumferential direction and three or more electric field sensors 14 in the vertical direction, it is possible to more accurately detect the state of plasma, which is generated from the process gas by using radio-frequency power in the VHF or UHF band.

In addition, the embodiments disclosed herein should be considered as illustrative and not restrictive in all respects. Indeed, the above-described embodiment may be embodied in various forms. Furthermore, the above-described embodiments may be omitted, substituted, or modified in various forms without departing from the scope and spirit of the appended claims.

Further, in relation to the above embodiments, the following supplementary notes are also disclosed.

### SUPPLEMENTARY NOTES

(1) A plasma processing apparatus includes:
a processing chamber disposed within a processing container;
a stage located within the processing chamber and on which a substrate is placed;
an upper electrode facing the stage;
a waveguide located along the upper electrode and through which radio-frequency power in a VHF band or a UHF band propagates;
a dielectric ring separating the processing chamber from the waveguide; and
four or more electric field sensors located in a circumferential direction of the dielectric ring,
wherein the four or more electric field sensors are disposed at positions where, when a reference position is 0, an angle formed by a straight line connecting a center of the dielectric ring and one of the four or more electric field sensors and a straight line connecting the center of the dielectric ring and each of the four or more electric field sensors is represented by 0, (t₁·π/2+π/6), (t₂·π/2+2π/6), and (t₃·π/2+3π/6), where t₁, t₂, and t₃ are integers including 0.
(2) The plasma processing apparatus of (1), wherein t₁, t₂, and t₃ are 0, and
wherein the four or more electric field sensors are located in the circumferential direction at intervals of π/6 within an area where the angle is 0 to π/2.
(3) The plasma processing apparatus of (1), wherein at least one selected from the group of t₁, t₂, and t₃ is 1 or more, and
wherein the four or more electric field sensors are located in the circumferential direction and distributed among two or more of four areas, whose angles are 0 to π/2, π/2 to π, π to 3π/2, and 3π/2 to 2π, respectively.
(4) The plasma processing apparatus of any one of (1) to (3), wherein the four or more electric field sensors are in contact with the dielectric ring.
(5) The plasma processing apparatus of any one of (1) to (4) further includes:
a controller that detects a bias in electric field distribution in a circumferential direction of the substrate based on sensor values output from the four or more electric field sensors.
(6) The plasma processing apparatus of (5) further includes:
a radio-frequency power supply that is connected to the stage and applies a bias voltage to the stage,
wherein the controller detects a bias in the bias voltage based on the sensor values output from the four or more electric field sensors.
(7) A plasma processing apparatus includes:
a processing chamber disposed within a processing container;
a stage located within the processing chamber and on which a substrate is placed;
an upper electrode facing the stage;
a waveguide located along the upper electrode and through which radio-frequency power in a VHF band or a UHF band propagates;
a dielectric ring separating the processing chamber from the waveguide; and
three or more electric field sensors located along a propagation direction of the radio-frequency power propagating through the dielectric ring or the waveguide and disposed within an area of ¼ of an effective wavelength of the radio-frequency power in the VHF band or the UHF band.
(8) The plasma processing apparatus of (7), wherein the three or more electric field sensors are in contact with the dielectric ring from a same direction.
(9) The plasma processing apparatus of (7), wherein the three or more electric field sensors are exposed to the waveguide from a same direction.
(10) The plasma processing apparatus of any one of (7) to (9) further includes:
a controller that detects a bias in electric field distribution in a radial direction of the substrate based on sensor values output from the three or more electric field sensors.
(11) The plasma processing apparatus of (10) further includes:
an electric field sensor located in a circumferential direction of the dielectric ring relative to at least one selected from the group of the three or more electric field sensors,
wherein the controller detects a tilt of the stage based on sensor values output from a plurality of electric field sensors located in the circumferential direction of the dielectric ring.

According to the present disclosure in some embodiments, it is possible to accurately monitor a state of plasma generated by radio-frequency power in a VHF band or a UHF band.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a processing chamber disposed within a processing container;
a stage located within the processing chamber and on which a substrate is placed;
an upper electrode facing the stage;
a waveguide located along the upper electrode and through which radio-frequency power in a VHF band or a UHF band propagates;
a dielectric ring separating the processing chamber from the waveguide; and
four or more electric field sensors located in a circumferential direction of the dielectric ring,
wherein the four or more electric field sensors are disposed at positions where, when a reference position is 0, an angle formed by a straight line connecting a center of the dielectric ring and one of the four or more electric field sensors and a straight line connecting the center of the dielectric ring and each of the four or more electric field sensors is represented by 0, (t₁·π/2+π/6), (t₂·π/2+2π/6), and (t₃·π/2+3π/6), where t₁, t₂, and t₃ are integers including 0.

2. The plasma processing apparatus of claim 1, wherein t₁, t₂, and t₃ are 0, and wherein the four or more electric field sensors are located in the circumferential direction at intervals of π/6 within an area where the angle is 0 to π/2.

3. The plasma processing apparatus of claim 2, further comprising:
a controller that detects a bias in electric field distribution in a circumferential direction of the substrate based on sensor values output from the four or more electric field sensors.

4. The plasma processing apparatus of claim 3, further comprising:
a radio-frequency power supply that is connected to the stage and applies a bias voltage to the stage,
wherein the controller detects a bias in the bias voltage based on the sensor values output from the four or more electric field sensors.

5. The plasma processing apparatus of claim 1, wherein at least one selected from the group of t₁, t₂, and t₃ is 1 or more, and
wherein the four or more electric field sensors are located in the circumferential direction and distributed among two or more of four areas, whose angles are 0 to π/2, π/2 to π, π to 3π/2, and 3π/2 to 2π, respectively.

6. The plasma processing apparatus of claim 1, wherein the four or more electric field sensors are in contact with the dielectric ring.

7. The plasma processing apparatus of claim 1, further comprising:
a controller that detects a bias in electric field distribution in a circumferential direction of the substrate based on sensor values output from the four or more electric field sensors.

8. A plasma processing apparatus comprising:
a processing chamber disposed within a processing container;
a stage located within the processing chamber and on which a substrate is placed;
an upper electrode facing the stage;
a waveguide located along the upper electrode and through which radio-frequency power in a VHF band or a UHF band propagates;
a dielectric ring separating the processing chamber from the waveguide; and
three or more electric field sensors located along a propagation direction of the radio-frequency power propagating through the dielectric ring or the waveguide and disposed within an area of ¼ of an effective wavelength of the radio-frequency power in the VHF band or the UHF band.

9. The plasma processing apparatus of claim 8, wherein the three or more electric field sensors are in contact with the dielectric ring from a same direction.

10. The plasma processing apparatus of claim 9, further comprising:
a controller that detects a bias in electric field distribution in a radial direction of the substrate based on sensor values output from the three or more electric field sensors.

11. The plasma processing apparatus of claim 10, further comprising:
an electric field sensor located in a circumferential direction of the dielectric ring relative to at least one selected from the group of the three or more electric field sensors,
wherein the controller detects a tilt of the stage based on sensor values output from a plurality of electric field sensors located in the circumferential direction of the dielectric ring.

12. The plasma processing apparatus of claim 8, wherein the three or more electric field sensors are exposed to the waveguide from a same direction.

13. The plasma processing apparatus of claim 8, further comprising:
a controller that detects a bias in electric field distribution in a radial direction of the substrate based on sensor values output from the three or more electric field sensors.
